(19) United States
(12) Patent Application Publication
(10) Pub. No.: US 2026/0205024 A1
(43) Pub. Date: Jul. 16, 2026

(54) ON-VEHICLE ELECTRIC COMPRESSOR

(71) Applicant: SANDEN CORPORATION, Isesaki-shi, Gunma (JP)

(72) Inventor: Eio ONODERA, Isesaki-shi, Gunma (JP)

(73) Assignee: SANDEN CORPORATION, Isesaki-shi, Gunma (JP)

(21) Appl. No.: 19/134,991

(22) PCT Filed: Nov. 28, 2023
(86) PCT No.: PCT/JP2023/042537

§ 371 Date: Jun. 2, 2025

(30) Foreign Application Priority Data
Dec. 20, 2022 (JP) 2022-202790

(51) Int. Cl. H02M 7/00; B60H 1/32; B60L 1/00; B60R 16/033; F04C 18/02; H05K 1/181; H05K 7/14

(52) U.S. Cl. CPC H02M 7/003; B60H 1/3223; B60R 16/033; F04C 18/0207; H05K 1/181; H05K 7/1427; B60H 2001/3292; B60L 1/003; F04C 2240/403; H05K 2201/10015; H05K 2201/1003

(57) ABSTRACT

Provided is a vehicle-mounted electric compressor that can improve an effect of reducing noise generated from, for example, an inverter circuit without increasing electrostatic capacitance of a Y-capacitor. A vehicle-mounted electric compressor (1) includes, in a metal housing (2), an inverter board (17) on which an inverter circuit (34) that converts direct current from a high-voltage battery (41) to alternating current and applies the alternating current to a motor (8) is mounted. Included are: a common mode coil (54) inserted into a high-voltage power line (46, 47) from the high-voltage battery (41); a Y-capacitor (56) connected between the high-voltage power line (46, 47) and the housing (2); and an inductor (57) connected in series to the Y-capacitor (56).

### TECHNICAL FIELD

The present invention relates to a vehicle-mounted electric compressor including, in a housing, an inverter board on which an inverter circuit is mounted.

### BACKGROUND ART

A vehicle air-conditioning system for air-conditioning the interior of an electric-powered vehicle uses a vehicle-mounted electric compressor including a motor instead of an engine-driven compression machine. In this case, an inverter circuit including a plurality of switching elements changes direct current voltage from a high-voltage (for example, approximately 300 V DC) vehicle-mounted battery to alternating current voltage, which is applied to the motor.

In addition, the switching of the switching elements of the inverter circuit is controlled by a control device. In this case, a high-voltage circuit including a high-voltage power line from the vehicle-mounted battery and a low-voltage circuit including the control device are placed on the same inverter board, and are attached in an inverter accommodation portion formed in a housing of the vehicle-mounted electric compressor.

Moreover, a common mode coil is connected to the high-voltage power line of the high-voltage circuit, and a Y-capacitor is connected between the high-voltage power line and the housing, so that common mode noise current flowing out from, for example, the inverter circuit is returned to a noise source (noise recovery) to improve EMI (refer to, for example, Patent Literature 1).

### CITATION LIST

### Patent Literature

Patent Literature 1: Japanese Patent No. 6571358

### SUMMARY OF INVENTION

### Problems to be Solved by Invention

Here, an LPF (Low Path Filter) including a common mode coil and a Y-capacitor is effective in reducing noise in a relatively low frequency range of approximately 1 MHz, and a resonant filter including only a Y-capacitor (and parasitic inductance) is effective in reducing high-frequency noise in the VHF band of 30 MHz to 50 MHz that is generated when switching elements of an inverter circuit are switched. However, their noise reduction effects are strongly affected by where on an inverter board (impedance characteristics).

Therefore, at the time of EMI testing upon prototype production, an operation of verifying the noise reduction effect in the VHF band is conventionally performed by forming a plurality of mounting patterns in advance so that a plurality of Y-capacitors can be placed at their respective positions on an inverter board and checking Y-capacitors at locations effective for high-frequency noise (impedances).

However, if many mounting patterns are laid out on the inverter board, there is a problem that the board size increases, resulting in an increase in the size of the vehicle-mounted electric compressor. Moreover, if mounting patterns unnecessary for mass production (unmounted patterns) are organized and integrated after an effective combination of locations of the Y-capacitors is found, there is also a problem that a result of EMI changes due to a change in the layout.

Furthermore, a Y-capacitor between the high-voltage power line and the housing (grounded to a chassis of a vehicle) needs to hold sufficient withstand voltage to secure the safety of the vehicle, but there is a limit to the withstand voltage per Y-capacitor in terms of product design, and in reality, approximately two to four Y-capacitors are connected in series and used. In terms of a currently widely used Y-capacitor, a product having maximum withstand voltage and maximum electrostatic capacitance in a vehicle-mounted product lineup is used. Therefore, it is difficult to increase electrostatic capacitance by re-selecting a component. Hence, if the capacitance is increased to improve EMI in the VHF band, many Y-capacitor groups in each of which two to four Y-capacitors are connected in series are further connected in parallel, resulting in a significant cost increase.

The present invention has been made to solve the known technical problems, and an object thereof is to provide a vehicle-mounted electric compressor that can improve an effect of reducing noise generated from, for example, an inverter circuit without increasing electrostatic capacitance of a Y-capacitor.

### Solution to Problems

A vehicle-mounted electric compressor according to the present invention includes, in a metal housing, an inverter board on which an inverter circuit that converts direct current from a vehicle-mounted battery to alternating current and applies the alternating current to a motor is mounted, the vehicle-mounted electric compressor including: a common mode coil inserted into a high-voltage power line from the vehicle-mounted battery; a Y-capacitor connected between the high-voltage power line and the housing; and an inductor connected in series to the Y-capacitor.

In a vehicle-mounted electric compressor according to the invention of claim 2, in the above invention, the Y-capacitor includes a ceramic capacitor group in which a plurality of surface mount ceramic capacitors is connected in series, and the inductor includes a surface mount chip inductor or a chip bead.

In a vehicle-mounted electric compressor according to the invention of claim 3, in the invention of claim 1, the inductor shifts a resonance frequency of the series circuit with the Y-capacitor to a lower frequency.

In a vehicle-mounted electric compressor according to the invention of claim 4, in the invention of claim 1, Y-capacitor mounting patterns are laid out in a plurality of places on the inverter board, and the inductor is connected to at least one of the Y-capacitors.

In a vehicle-mounted electric compressor according to the invention of claim 5, in the above inventions, the high-voltage power line from the vehicle-mounted battery, a high-voltage circuit including the Y-capacitor and the inductor, and a low-voltage circuit including a control device that controls the inverter circuit are placed on the inverter board.

### Effects of Invention

According to the present invention, a vehicle-mounted electric compressor having, in a metal housing, an inverter board on which an inverter circuit that converts direct current from a vehicle-mounted battery to alternating current and applies the alternating current to a motor is mounted includes: a common mode coil inserted into a high-voltage power line from the vehicle-mounted battery; a Y-capacitor connected between the high-voltage power line and the housing; and an inductor connected in series to the Y-capacitor. Therefore, it is possible to shift a resonance frequency of the series circuit of the Y-capacitor and the inductor to a lower frequency without increasing electrostatic capacitance of the Y-capacitor.

Consequently, even if the Y-capacitor includes a series ceramic capacitor group in which surface mount ceramic capacitors are connected in series and the combined capacitance decreases and the resonance frequency increases, it is possible to prevent an outflow of switching surge noise in the VHF band that is generated when the motor of the vehicle-mounted electric compressor is driven by causing the Y-capacitor and the inductor to efficiently return the switching surge noise to the inverter circuit being a noise source to recover the switching surge noise, and therefore, it is possible to improve EMI.

Here, radiated noise generated from the control device is shielded by the metal housing in which the inverter board is accommodated. Therefore, there is no problem in particular.

Moreover, the need to further connect the series ceramic capacitor groups in parallel to increase the electrostatic capacitance is also eliminated, and the connection to the inexpensive inductor including a chip inductor or chip bead will do. Therefore, it is possible to achieve a significant cost reduction and a reduction in the size of the vehicle-mounted electric compressor.

Moreover, if a plurality of Y-capacitor mounting patterns is laid out on the inverter board first and then the Y-capacitors are mounted, EMI can be improved by connecting the inductor in series to at least one of the Y-capacitors. Therefore, it is not necessary to perform an operation of determining mounting patterns effective for EMI and then organizing and integrating them upon prototype production in contrast to before, and there is also no reduction in reproducibility of EMI that occurs at the time of arranging and integrating unmounted patterns. Therefore, it is also possible to encourage a significant reduction in the development period.

This is extremely effective for a vehicle-mounted electric compressor in which a high-voltage circuit and a low-voltage circuit are placed on an inverter board.

### BRIEF DESCRIPTION OF DRAWINGS

FIG. 1 is a schematic cross-sectional view of a vehicle-mounted electric compressor of an example of the present invention.

FIG. 2 is a block diagram of an electric circuit of the vehicle-mounted electric compressor of FIG. 1 in a case of assuming EMI measurements.

FIG. 3 is a plan view of an inverter board of the vehicle-mounted electric compressor of FIG. 1.

FIG. 4 is an enlarged view of an inductor part of FIG. 3.

FIG. 5 is an equivalent circuit diagram of a Y-capacitor to which an inductor is connected in series.

FIG. 6 is an equivalent circuit diagram of the Y-capacitor only.

FIG. 7 is a diagram for explaining impedance characteristics in cases of FIGS. 5 and 6.

### DESCRIPTION OF EMBODIMENTS

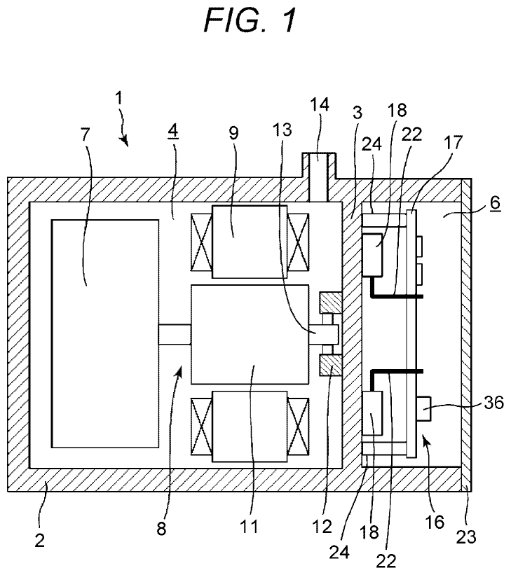

An embodiment of the present invention is described in detail hereinafter on the basis of the drawings. Firstly, a vehicle-mounted electric compressor (what is called an inverter-integrated vehicle-mounted electric compressor) 1 of an example to which the present invention is applied is described with reference to FIG. 1. Note that the vehicle-mounted electric compressor 1 of the example configures a part of a refrigerant circuit of a vehicle air-conditioning system that is mounted on an electric-powered vehicle such as a hybrid vehicle or an electric vehicle.

### (1) Configuration of Vehicle-Mounted Electric Compressor 1

In FIG. 1, a partition wall 3 intersecting with an axial direction of a cylindrical metal (aluminum having a predetermined thickness in the example) housing 2 of the vehicle-mounted electric compressor 1 divides the inside of the housing 2 into a compression mechanism accommodation portion 4 and an inverter accommodation portion 6 and, for example, a scroll compression mechanism 7 and a motor 8 that drives the compression mechanism 7 are accommodated in the compression mechanism accommodation portion 4.

In this case, the motor 8 of the example is an IPMSM (Interior Permanent Magnet Synchronous Motor) including a stator 9 fixed to the housing 2 and a rotor 11 that rotates inside the stator 9.

A bearing portion 12 is formed on a central portion on a compression mechanism accommodation portion 4 side of the partition wall 3. One end of a drive shaft 13 of the rotor 11 is supported by the bearing portion 12, and the other end of the drive shaft 13 is coupled to the compression mechanism 7. A suction port 14 is formed near the partition wall 3 at a position corresponding to the compression mechanism accommodation portion 4 of the housing 2. When the rotor 11 (the drive shaft 13) of the motor 8 rotates to drive the compression mechanism 7, a low-temperature refrigerant that is working fluid flows into the compression mechanism accommodation portion 4 of the housing 2 through the suction port 14, and is sucked into and compressed by the compression mechanism 7.

It is configured in such a manner that the refrigerant that has been compressed by the compression mechanism 7 to increase in temperature and pressure is then discharged to the refrigerant circuit outside the housing 2 through an unillustrated discharge port. Moreover, the low-temperature refrigerant that has flowed in through the suction port 14 passes near the partition wall 3 and then around the motor 8, and is sucked into the compression mechanism 7, which results in also cooling the motor 8 and the partition wall 3.

In addition, an inverter device 16 that controls the drive of the motor 8 is accommodated in the inverter accommodation portion 6 divided by the partition wall 3 from the compression mechanism accommodation portion 4. In this case, the inverter device 16 is configured in such a manner as to supply power to the motor 8 via a sealed terminal and a lead wire that penetrate the partition wall 3.

### (2) Structure of Inverter Device 16

The inverter device 16 of the example includes an inverter board 17, six switching elements 18 wired on one side of the inverter board 17, a control device 36 placed on the other side of the inverter board 17, and an unillustrated HV connector and LV connector. Each of the switching elements 18 includes an insulated-gate bipolar transistor (IGBT) of which the gate portion incorporates a MOS structure in the example.

In this case, the switching elements 18 configure a three-phase inverter circuit 34 described below, and a terminal portion 22 of the each of the switching elements 18 is connected to the inverter board 17. The inverter device 16 assembled in this manner is then accommodated in the inverter accommodation portion 6 with the one side having the switching elements 18 facing the partition wall 3, is attached to the partition wall 3, and is blocked with a cover 23. In this case, the inverter board 17 is fixed to the partition wall 3 via a boss portion 24 standing on the partition wall 3.

In this manner, in a state where the inverter device 16 is attached to the partition wall 3, the switching elements 18 are in close contact with the partition wall 3 directly or via a predetermined thermally conductive insulating material, and are in a heat exchange relationship with the partition wall 3 of the housing 2. In addition, the partition wall 3 is cooled by the refrigerant sucked into the compression mechanism accommodation portion 4 as described above; therefore, the switching elements 18 have a heat exchange relationship with the sucked refrigerant via the partition wall 3, and are cooled by the refrigerant sucked into the compression mechanism accommodation portion 4 via the thick partition wall 3. The switching elements 18 themselves dissipate heat to the refrigerant via the partition wall 3. In other words, the housing 2 (the partition wall 3) is a heat sink for the switching elements 18.

### (3) Circuit Configuration of Inverter Device 16

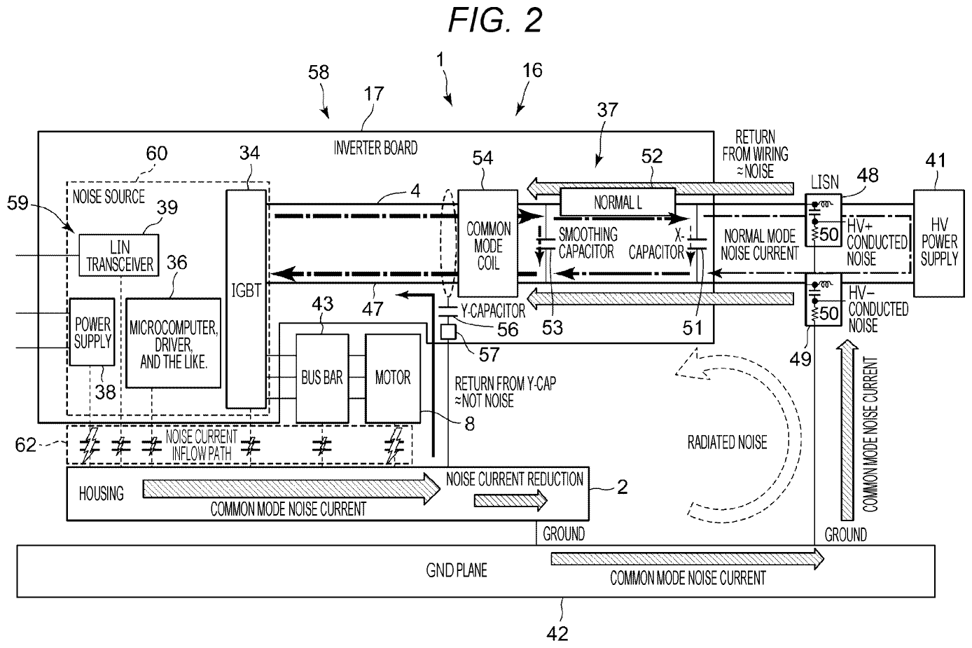

Next, in FIG. 2, the inverter device 16 of the present invention is configured, including the above-mentioned inverter circuit 34 that includes an IGBT and operates the motor 8, the above-mentioned control device 36 that includes a microcomputer and a driver and controls the inverter circuit 34, a high-voltage circuit filter (EMI filter) 37, a low-voltage power supply 38, and a LIN transceiver 39, which are wired on the above-mentioned inverter board 17 and accommodated in the inverter accommodation portion 6 as described above.

Note that the motor 8 of the vehicle-mounted electric compressor 1 and a high-voltage battery (an HV power supply; a vehicle-mounted battery) 41 with, for example, approximately 300 V DC for supplying power to and driving an unillustrated drive motor are mounted on a vehicle, and the inverter device 16 is connected by the above-mentioned unillustrated HV connector to the high-voltage battery 41.

In FIG. 2, in a case of EMI measurements for a component (the electric compressor only), a reference numeral 46 denotes a positive high-voltage power line connected to the positive side (+) of the high-voltage battery 41 via a LISN (line impedance stabilization network) 48, a reference numeral 47 denotes a negative high-voltage power line connected to the negative side (−) of the high-voltage battery 41 via a LISN 49, and the high-voltage circuit filter 37 is connected to the positive high-voltage power line 46 and the negative high-voltage power line 47. In a case of the vehicle, the LISN 48 and the LISN 49 are not connected.

The high-voltage circuit filter 37 is configured, including an X-capacitor 51 connected between the positive high-voltage power line 46 and the negative high-voltage power line 47, a normal mode coil 52 inserted into the positive high-voltage power line 46 at a stage subsequent to the X-capacitor 51, a smoothing capacitor 53 connected between the positive high-voltage power line 46 and the negative high-voltage power line 47 at a stage subsequent to the normal mode coil 52, a common mode coil 54 connected to a stage subsequent to the smoothing capacitor 53, a plurality of Y-capacitors (represented by a reference numeral 56) connected between each of the positive high-voltage power line 46 and the negative high-voltage power line 47 and the housing 2 at a stage subsequent to the common mode coil 54, and an inductor 57 connected in series to one of the Y-capacitors 56 in the example.

The above X-capacitor 51 is a capacitor for reducing normal mode noise, and the Y-capacitors 56 are capacitors for reducing common mode noise. Moreover, the smoothing capacitor 53 is a capacitor for smoothing voltage ripple and regarding a high frequency as a short circuit as a starting point of impedance balance. The high-voltage circuit filter 37 is connected between the high-voltage battery 41 and the inverter circuit 34, and has an effect of reducing EMI noise generated by switching of the inverter circuit 34.

Note that the function of the inductor 57 is described in detail below. Moreover, the inverter circuit 34 is wired and connected by a bus bar 43 to the motor 8, and the housing 2 is grounded (conducted) to a vehicle body 42 (ground plane).

For example, the above positive high-voltage power line 46 and negative high-voltage power line 47, the high-voltage circuit filter 37 including the X-capacitor 51, the normal mode coil 52, the smoothing capacitor 53, the common mode coil 54, the Y-capacitors 56, and the inductor 57, and the inverter circuit 34 configure a high-voltage circuit 58 of the inverter device 16. Moreover, for example, the control device 36, the low-voltage power supply 38, and the LIN transceiver 39 configure a low-voltage circuit 59 of the inverter device 16. In the example, the high-voltage circuit 58 and the low-voltage circuit 59 are placed in proximity to each other on the same inverter board 17.

### (4) Structure of Inverter Board 17

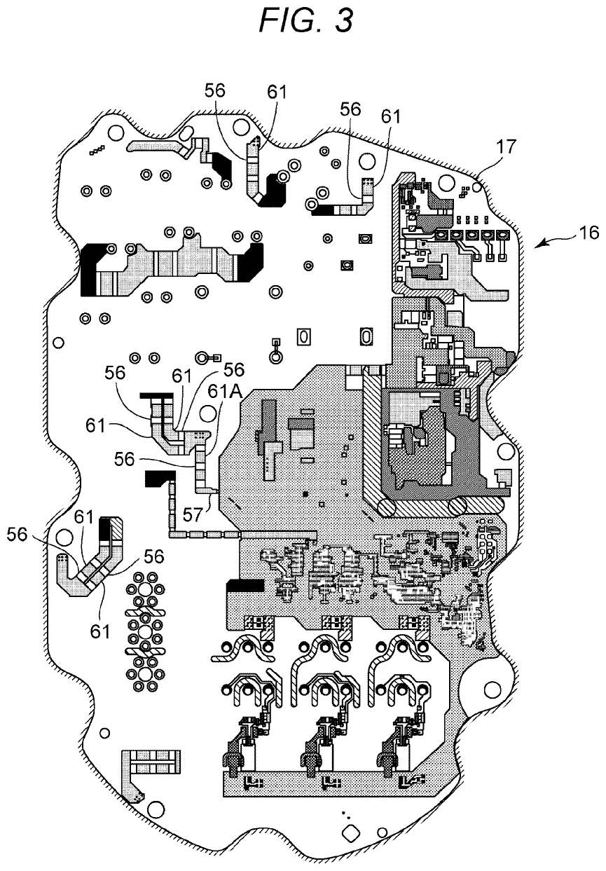

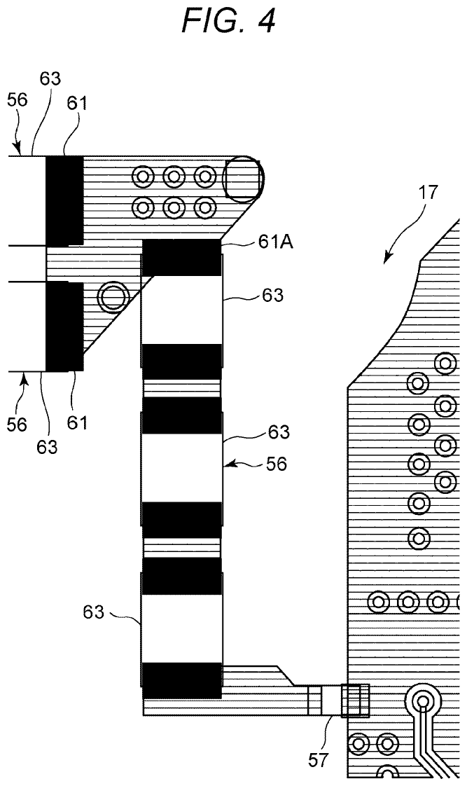

Next, FIG. 3 is a plan view of the inverter board 17, and FIG. 4 is an enlarged view of the inductor 57 part of FIG. 3. The inverter board 17 is a printed board on which the above-mentioned elements of the inverter device 16 are wired. As described above, the Y-capacitors 56 effective for high frequency noise are strongly affected by their locations (impedance characteristic) on the inverter board 17. Therefore, mounting patterns 61 (including 61A) are laid out in advance on the inverter board 17 in a plurality of places assumed to be effective as attachment places of the Y-capacitors 56, respectively.

In the example, the mounting patterns 61 of the Y-capacitors 56 are formed in seven places on the inverter board 17 that are considered to be effective, and the Y-capacitors 56 are connected to the mounting patterns 61 respectively. In the case of the example, one Y capacitor 56 includes a ceramic capacitor group in which a plurality of surface mount ceramic capacitors 63 is connected in series to secure a sufficient withstand voltage for the purpose of securing the safety of the vehicle. Note that two to four series-connected surface mount ceramic capacitors 63 are used in reality. In this example, one Y-capacitor 56 includes a ceramic capacitor group in which three ceramic capacitors are connected in series.

In addition, in the example, the inductor 57 is connected in series to the Y capacitor 56 connected to the mounting pattern indicated with the reference numeral 61A in FIGS. 3 and 4. In the case of the example, the inductor 57 uses a surface mount chip inductor. Note that a chip bead may be used as the inductor 57. Moreover, the number of places is not limited to one, but the inductors 57 may be connected in series to some of the Y-capacitors 56, or the inductors 57 may be connected in series to all the Y-capacitors 56 respectively, depending on the state of the effect.

### (5) Operation of Inverter Device 16

The inverter circuit 34 is configured, including the above-mentioned six switching elements 18 of the three-phase bridge connection, and each of the switching elements 18 is controlled by a gate drive signal produced by a gate driver included in the control device 36. The control device 36 is configured, including a microcomputer (CPU) and the gate driver, and causes the gate driver to switch the each of the switching elements 18 of the inverter circuit 34 to perform PWM modulation and consequently changes direct current voltage of the high-voltage battery 41 to alternating current voltage of a predetermined frequency to apply the alternating current voltage to the motor 8.

### (6) Noise Path of Inverter Device 16

Here, the switching elements 18 configuring the inverter circuit 34 generate a surge voltage (spike voltage) accompanied by switching; therefore, the inverter circuit 34, the control device 36, the low-voltage power supply 38, and the LIN transceiver 39 become a noise source 60. Noise current generated from the noise source 60 flows out to the housing 2 via the inverter board 17, the bus bar 43, and stray capacitance between the motor 8 and the housing 2 (a noise current inflow path indicated with a reference numeral 62 in FIG. 2). This current becomes common mode noise current and flows from the housing 2 to the vehicle body 42 (indicated by hatched arrows in FIG. 2), and flows to the LISNs 48 and 49 at the time of EMI measurements for the component. Therefore, it is detected as noise. Thereafter, the noise returns from the wiring to the inverter board 17 (noise). In FIG. 2, a broken line arrow indicates radiated noise generated by the common mode noise current, and dot-and-dash line arrows indicate normal mode noise current. Note that radiated noise is generated regardless of whether it is the component or the vehicle.

### (7) Effect of Y-Capacitor 56 and Inductor 57

A part of the common mode noise current that has flowed out from the above-mentioned noise source 60 returns to (is recovered by) the noise source 60 via the Y-capacitor 56 and the inductor 57 (a solid arrow passing through the Y-capacitor 56 in FIG. 2). Therefore, the common mode noise current is reduced accordingly.

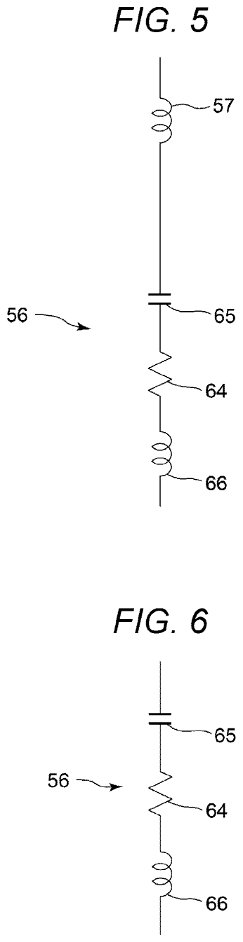

Here, a difference in noise improvement effect between a case of the Y-capacitor 56 only and a case where the inductor 57 is connected in series to the Y-capacitor 56 as in the present invention is described with reference to FIGS. 5 to 7. FIG. 5 is an equivalent circuit diagram in a case where the inductor 57 is connected in series to the Y-capacitor 56 connected to the mounting pattern 61A as illustrated in FIG. 4, and FIG. 6 is an equivalent circuit diagram in a case of the Y-capacitor 56 only without being connected to the inductor 57. In each drawing, a reference numeral 65 denotes the capacitance of the Y-capacitor 56, a reference numeral 64 denotes parasitic series resistance of the Y-capacitor 56, and a reference numeral 66 denotes parasitic series inductance of the Y-capacitor 56.

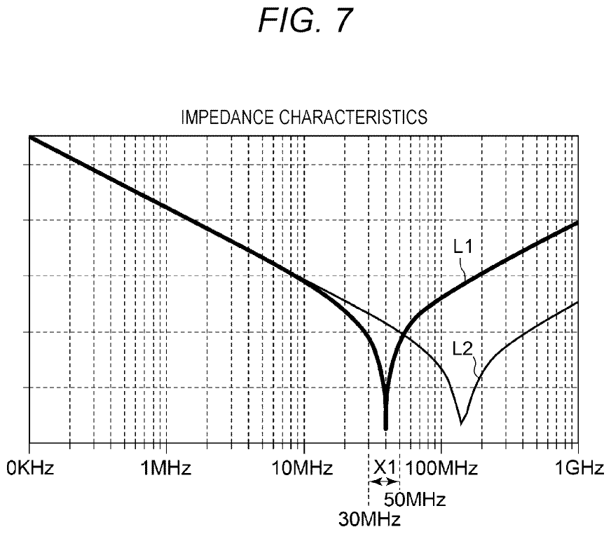

In addition, in FIG. 7, a reference numeral L1 denotes impedance characteristics in the case of FIG. 5, and a reference numeral L2 denotes impedance characteristics in the case of FIG. 6. In the example, as described above, one Y-capacitor 56 includes a ceramic capacitor group in which three surface mount ceramic capacitors 63 are connected in series to secure sufficient withstand voltage for the purpose of securing the safety of the vehicle. Therefore, in the case of the Y-capacitor 56 only (FIG. 6), the combined capacitance decreases, and a resonance frequency (a frequency at which impedance is the lowest) increases as indicated with the reference numeral L2 in FIG. 7 to be located at approximately 150 MHz in the example.

Here, the improved characteristics of the common mode noise by the Y-capacitor are enhanced as the impedance reduces. On the other hand, the noise current generated at the time of switching the switching elements 18 of the inverter circuit 34 is at 30 MHz to 50 MHz, and in the case of the Y-capacitor 56 only as illustrated in FIG. 6, the impedance does not completely decrease in the band of 30 MHz to 50 MHz (a range indicated with a reference numeral X1 in FIG. 7), and sufficient noise improvement characteristics cannot be expected.

On the other hand, if the inductor 57 is connected in series to the Y-capacitor 56 as illustrated in FIG. 5, the impedance characteristics are as illustrated with L1 in FIG. 7. In the present invention, the inductor 57 is connected in series to the Y-capacitor 56. Therefore, the resonance frequency is shifted to a lower frequency. Note that in the example, it is configured in such a manner that the resonance frequency is shifted to the band of 30 MHz to 50 MHz (X1 in FIG. 7), and the impedance characteristics in this band are greatly improved.

Consequently, switching surge noise in the VHF band that is generated when the motor 8 is driven is efficiently returned by the Y-capacitor 56 and the inductor 57 to the inverter circuit 34 of the noise source 60 to be recovered, and is prevented from flowing out to the outside.

Note that if the inductor 57 is connected in series (L1), the resonance frequency is shifted to a lower frequency; therefore, the impedance is higher at frequencies exceeding 50 MHz (particularly 100 MHz or higher) than in the case of the Y capacitor 56 only (L2) (L1>L2: FIG. 7). Noise at 100 MHz or higher is mainly noise generated from the control device 36. However, the impedance of a path through which the noise current passes from the control device 36 to the housing 2 is very high, and it is not necessary to recover the noise by use of the Y-capacitor. Moreover, in terms of the radiated noise generated directly from the control device 36, the inverter board 17 is accommodated in and shielded by the inverter accommodation portion 6 of the housing 2 made of thick aluminum as in the example. Therefore, a concern about leakage to the outside can be almost ignored.

As described in detail above, according to the present invention, the vehicle-mounted electric compressor 1 having, in the aluminum housing 2, the inverter board 17 on which the inverter circuit 34 that converts direct current voltage from the high-voltage battery 41 to alternating current voltage and applies the alternating current voltage to the motor 8 is mounted includes: the common mode coil 54 inserted into the positive high-voltage power line 46 and the negative high-voltage power line 47 from the high-voltage battery 41; the Y-capacitors 56 connected between either of the power lines 46 and 47 and the housing 2; and the inductor 57 connected in series to the Y-capacitor 25. Therefore, it is possible to shift the reference frequency of the series circuit of the Y-capacitor 56 and the inductor 57 to a lower frequency without increasing the electrostatic capacitance of the Y-capacitor 56.

Consequently, even if the Y-capacitor 56 includes a series ceramic capacitor group in which the surface mount ceramic capacitors 63 are connected in series and the combined capacitance decreases and the resonance frequency increases, the switching surge noise of 30 MHz to 50 MHz that is generated when the motor 8 of the vehicle-mounted electric compressor 1 is driven can be efficiently returned by the Y-capacitor 56 and the inductor 57 to the inverter circuit 34 that is a noise source and recovered to prevent the switching surface noise from flowing to the outside, and EMI can be improved.

Moreover, the radiated noise generated from the control device 36 is shielded by the aluminum housing 2 in which the inverter board 17 is accommodated. Therefore, there is no problem in particular.

Moreover, the need to further connect the series ceramic capacitor groups in parallel to increase the electrostatic capacitance of the Y-capacitor 56 is also eliminated, and the connection to the inexpensive inductor 57 including a chip inductor or chip bead will do. Therefore, it is possible to achieve a significant cost reduction and a reduction in the size of the vehicle-mounted electric compressor 1.

Moreover, if the mounting patterns 61 of the Y-capacitors 56 are laid out on the inverter board 17 first and then the Y-capacitors 56 are mounted, EMI can be improved by connecting the inductor 57 in series to at least one of the Y-capacitors 56. Therefore, it is not necessary to perform the operation of determining the mounting patterns 61 effective for EMI and then arranging and integrating them upon prototype production in contrast to before, and there is also no reduction in reproducibility of EMI that occurs at the time of arranging and integrating unmounted patterns. Therefore, it is also possible to encourage a significant reduction in the development period.

This is extremely effective since in the vehicle-mounted electric compressor 1 in which the high-voltage circuit 58 and the low-voltage circuit 59 are placed close to each other on the inverter board 17 as in the example, the influence of noise from the high-voltage circuit 58 on the low-voltage circuit 59 can be greatly improved.

Note that configurations and numerical values are not limited to the specific configurations and numerical values presented in the example, and various modifications can be made without departing from the purport of the present invention.

### LIST OF REFERENCE SIGNS

1 Vehicle-mounted electric compressor
2 Housing
3 Partition wall
6 Inverter accommodation portion
8 Motor
16 Inverter device
17 Inverter board
18 Switching element
34 Inverter circuit
36 Control device
37 High-voltage circuit filter
41 High-voltage battery (vehicle-mounted battery)
46 Positive high-voltage power line (high-voltage power line)
47 Negative high-voltage power line (high-voltage power line)
54 Common mode coil
56 Y-capacitor
57 Inductor
58 High-voltage circuit
59 Low-voltage circuit
69 Noise source
61 (61A) Mounting pattern
63 Ceramic capacitor

1. A vehicle-mounted electric compressor including, in a metal housing, an inverter board on which an inverter circuit that converts direct current from a vehicle-mounted battery to alternating current and applies the alternating current to a motor is mounted, the vehicle-mounted electric compressor comprising:
a common mode coil inserted into a high-voltage power line from the vehicle-mounted battery;
a Y-capacitor connected between the high-voltage power line and the housing; and
an inductor connected in series to the Y-capacitor.

2. The vehicle-mounted electric compressor according to claim 1, wherein
the Y-capacitor includes a ceramic capacitor group in which a plurality of surface mount ceramic capacitors is connected in series, and
the inductor includes a surface mount chip inductor or a chip bead.

3. The vehicle-mounted electric compressor according to claim 1, wherein the inductor shifts a resonance frequency of the series circuit with the Y-capacitor to a lower frequency.

4. The vehicle-mounted electric compressor according to claim 1, wherein
Y-capacitor mounting patterns are laid out in a plurality of places on the inverter board, and
the inductor is connected to at least one of the Y-capacitors.

5. The vehicle-mounted electric compressor according to claim 1, wherein the high-voltage power line from the vehicle-mounted battery, a high-voltage circuit including the Y-capacitor and the inductor, and a low-voltage circuit including a control device that controls the inverter circuit are placed on the inverter board.

6. The vehicle-mounted electric compressor according to claim 2, wherein the high-voltage power line from the vehicle-mounted battery, a high-voltage circuit including the Y-capacitor and the inductor, and a low-voltage circuit including a control device that controls the inverter circuit are placed on the inverter board.

7. The vehicle-mounted electric compressor according to claim 3, wherein the high-voltage power line from the vehicle-mounted battery, a high-voltage circuit including the Y-capacitor and the inductor, and a low-voltage circuit including a control device that controls the inverter circuit are placed on the inverter board.

8. The vehicle-mounted electric compressor according to claim 4, wherein the high-voltage power line from the vehicle-mounted battery, a high-voltage circuit including the Y-capacitor and the inductor, and a low-voltage circuit including a control device that controls the inverter circuit are placed on the inverter board.
